(19) United States
(12) Patent Application Publication
(10) Pub. No.: US 2006/0006366 A1
(43) Pub. Date: Jan. 12, 2006

(54) Wave length shifting compositions for white emitting diode systems

(76) Inventors: Vladimir Abramov, Moscow (RU); Naum Soshchin, Moscow (RU); Valery Sushkov, Moscow (RU); Nikolai Scherbakov, Moscow (RU); Valentin Scherbakov, Moscow (RU); Alexander Shishov, Moscow (RU)

Correspondence Address: Joseph Page, P.O. Box 757, La Jolla, CA, 92038, US

(21) Appl. No.: 10/885,557

(22) Filed: Jul. 6, 2004

(51) Int. Cl. C09K 11/08; H01L 29/22; H01L 29/227; H01L 33/00; C09K 11/04

(52) U.S. Cl. 252/301.4 R; 257/98

(57) ABSTRACT

Special high performance wavelength shifting compositions has been discovered and devised. Further, these compositions when properly distributed in a bulk medium having cooperative properties forms new media having totally unique and useful characteristics. In particular, a special phosphor is devised having a dual peak spectral output when stimulated with high energy photonic input. A dual activator formula is created such that simple manipulation of specified ratios permits flexibility in tuning of color temperature output of the phosphor emitter combination. When prepared with preferred particle sizes and densities, performance improvements are observed. Finally, these phosphors are combined with other special binder materials to form colloid media with well designed optical interaction cross section whereby light emitted from a high intensity blue diode semiconductor will experience just enough wavelength shift in precisely the desired portions of the spectrum, with high efficiency, to form a white LED not found in other systems.

### BACKGROUND OF THE INVENTIONS

2. Field

The following inventions disclosure is generally concerned with light emitting compositions of matter and more specifically concerned with specially formulated compositions for improved performance in white emitting diode systems.

2. Prior Art

Practitioners of the optical sciences will be quick to point out several techniques for simulating a white-light, light emitting diode LED. ‘Simulate’ is specified as the intrinsic properties of LEDs demand that they emit light in relatively narrow bands; white light is by definition, a broad optical spectral band. To date, there are no real ‘broadband’ LED emitters which truly produce white light at the diode junction in sufficient quantity and efficiency so as to be commercially viable. Rather, there are several configurations employed to mix light from a plurality of narrow band individual sources. For example, one might combine in close proximity red, green, and blue emitting diode chips. If the associated brightness of each is similar, and the system is viewed from sufficiently far away whereby the eye does not resolve the individual chips, it will appear to be a white LED. Many difficulties are found in such systems and these are currently not in favor. They suffer from poor color temperature balance, unsuitable color rendering index, and complex macro-packaging problems, among others.

A very useful alternative which has recently become enabled via high brightness blue emitting diodes is realized in the following manner. A high brightness blue LED is placed on a substrate. A coating or slurry of phosphor is applied thereon the top of the semiconductor chip. This special phosphor is stimulated by blue light emitted by the chip. When stimulated, the phosphor emits light, albeit with less energy (longer wavelength) than the stimulating light. Phosphors which are stimulated by blue light and emit yellow light have been used to form ‘White’ LEDs. It is tricky to get the coating of phosphor just right. The interaction cross section dictates how much of the blue light is converted to yellow. As it is desirable to have just the right amount of blue light mix with just the right amount of yellow light, the thickness and density of the phosphor coating has a great effect on the interaction cross section. The nature of the phosphor grain also effects the interaction cross section and scattering properties. In particular, the size and shape of the phosphor particles changes the interaction characteristics. Because geometries particular to semiconductor chips and LED device packaging, commonly used techniques present problems in angular uniformity, among others. Additionally, simply mixing yellow and blue light does not precisely result a true broad band. For example, some of these configurations suffer from a ‘cool’ appearance or white which lacks warming colors; i.e. those colors near the red bands. Metrics used to characterize color rendering tend to suggest these white LEDs are less than perfectly desirable.

For example, such configurations typically employ a blue emitting LED with a wavelength of about 455 nm and a yellow emitting phosphor such as cerium doped YAG, yttrium-aluminum-garnet, having its peak secondary emission at about 570 nm the semi-width of the spectrum, that equals about 140 nm. This results in a color temperature of about 8000° K. and a low CRI of about 70.

Many interesting systems have also been designed to arrive at a high performance white LED with good quality color metrics. These include but are not limited to the inventions taught in the following patents which are most closely related to the present inventions.

U.S. Pat. No. 5,998,925 describes systems where a YAG based phosphor is used to convert blue light emitted from a nitride semiconductor into yellow light.

While systems and inventions of the art are designed to achieve particular goals and objectives, some of those being no less than remarkable, these inventions have limitations which prevent their use in new ways now possible. Inventions of the art are not used and cannot be used to realize the advantages and objectives of the inventions taught herefollowing.

### SUMMARY OF THE INVENTIONS

Comes now, Abramov, V. S. et al, with inventions of white emitting illumination systems including compositions of light emitting materials more precisely those which operate to shift wavelengths of light. It is a primary function of these compositions to provide white light systems having improved color temperature and color rendering index characteristics. It is a contrast to prior art methods and devices that those systems do not offer the color temperature and color rendering indices which are attainable with new compositions.

Systems taught herefollowing eliminate shortcomings of previous white LED systems. By careful design and application, improved wavelength shifting mechanisms are used to form white LEDs having preferred metrics. For example, LEDs taught here can have a color temperature between 2,500K and 11,000K. In addition, they have higher output due to improved efficiency. Further, the techniques presented permit simplification in manufacturing and are accompanied by a cost reduction.

A high performance composition of matter, a phosphor class, has been discovered which is well aligned and cooperates with the attributes and objectives found in broadband LED systems. The se classes of phosphor may be characterized as ‘YAG phosphors’. More particularly, these are YAG phosphors having dual activators. Further, these phosphor compositions, when properly prepared and properly distributed within a special medium or ‘binder’ has superior performance characteristics not found in similar white LED designs. In particular, the composition above will produce a spectrum having two primary peaks precisely and controllably located in the spectrum. In view of the emission wavelengths of best high brightness LED semiconductors, i.e. blue diodes, the spectrum cooperates to produce a preferred white spectrum as measured by standard colorimetry techniques.

### OBJECTIVES OF THESE INVENTIONS

It is a primary object of these inventions to provide new compositions for use in secondary emission.

It is an object of these inventions to provide phosphor compositions to upshift the wavelengths of blue or UV emitting diodes.

It is a further object to provide specially blended compositions having preferred emission characteristics for improved white light emission.

A better understanding can be had with reference to detailed description of preferred embodiments and with reference to appended drawings. Embodiments presented are particular ways to realize these inventions and are not inclusive of all ways possible. Therefore, there may exist embodiments that do not deviate from the spirit and scope of this disclosure as set forth by the claims, but do not appear here as specific examples. It will be appreciated that a great plurality of alternative versions are possible.

### BRIEF DESCRIPTION OF THE DRAWING FIGURES

These and other features, aspects, and advantages of these instant inventions will become better understood with regard to the following description, appended claims and drawings where:

FIG. 1 is a spectrum diagram showing highly unique emission characteristics;

FIG. 2 is a prior art diagram showing spectral differences in previous approaches;

FIG. 3 is a chromaticity diagram showing general locus plotted from sample data;

FIG. 4 illustrates a solution for material distribution and relationships with cooperating elements.

### PREFERRED EMBODIMENTS OF THESE INVENTIONS

In accordance with each of the preferred embodiments of these inventions, there are provided compositions for wavelength shifting of high energy LEDs to form a white spectral output. It will be appreciated that each of the embodiments described include a composition and apparatus and that the composition and apparatus of one preferred embodiment may be different than the composition and apparatus of another embodiment.

A broadband light emitting source based upon a diode semiconductor and unique phosphor forms the basis for these inventions. In particular, a YAG based phosphor is combined with a high energy light emitting diode. The diode, a semiconductor chip, is mounted to a substrate having electrical, mechanical and optical support. Onto the semiconductor chip, a material which at least partly consists of phosphor grains is applied to form a coating over the chip. A portion of light emitted from the semiconductor interacts with the phosphor and excites it into a high energy state. The phosphor does not stay at this excited state, but rather it decays back to a ground state via emissive and non-emissive energy transitions. Re-emission at longer wavelengths occurs as a natural part of the phosphor energy decay. These longer wavelengths are perceived as different colors in the spectrum. By mixing several colors together, it is possible to generate a white appearing system.

To produce white LEDs, a special kind of phosphor is necessary. While many types of phosphor is commonly used to emit light of various colors, common phosphors can not be used in diode systems because they are not easily excited. Common phosphors require high energy electron inputs to sufficiently pump them with energy where they will re-emit in their prescribed colors. For LEDs, phosphors which are pumped by photonic input are necessary. These are very special and highly efficient since the re-emission wavelengths are so close to the pump wavelengths.

One special class of phosphor which responds in this fashion is a YAG based phosphor. Yttrium-Aluminum-Garnet, or YAG, is a material which forms the basis of some high efficiency phosphors. YAG phosphors may be pumped by photonic input and particularly by blue light having wavelengths at or about 450 nanometers. These phosphors will re-emit light in the yellow portion of the spectrum at about 550 nanometers.

Not all of the blue light emitted by the diode is converted to yellow light. There is a limited and finite probability that a conversion will take place as some of the blue light will pass the coating without being absorbed and re-emitted. This is by design. When an observer views light from the device, she sees blue light and yellow light simultaneously. The blue light is light directly from the chip which has not had phosphor interaction, and the yellow light is from phosphor reemission activity. To a human viewer, this tends to appear ‘whitish’. If the density of phosphor is too great, then the device output will be mostly yellow and there will be an insufficient amount of blue. If there is too little phosphor the output light will be too blue.

In either case, the light appears as a white having a ‘cool’ look; i.e. a bluis white. This is readily understood in view of the lack of red light present; i.e. warm color. White LED systems based upon blue emitting chips and YAG based phosphors tend to have light outputs of low color temperature. This is not always desirable.

Attempts have been made to improve the color temperature of these devices. By adjusting the phosphor chemistry, it is possible to shift the re-emission spectrum towards longer wavelengths. In particular, by manipulating the ratio of yttrium to gadolinium in the phosphor composition, the peak of the re-emission curve is moved slightly to longer wavelengths thereby yielding a warmer white light output. Because the impossibility for large shifts, this solution is ineffective for producing white light with warm tones.

Instead, a YAG phosphor can be manipulated by adding a second activator component. YAG phosphors of the art are typically activated with cerium. The peak emission in the yellow portion of the spectrum is attributable to the cerium activator. A second activation element can be added to stimulate an emission peak in the red part of the spectrum.

To this end, a YAG phosphor of two activators, that is cerium and praseodymium, is first presented here. YAG phosphors activated via both cerium and praseodymium include a very unique spectral output. The spectrum includes a red peak, due to the praseodymium, at about 610 nanometers. When viewed, the Red-Yellow-Blue combination appears ‘White’. It is not like the cool white of previous YAG phosphors but rather, it is warmer and more pleasant. The added praseodymium couples more energy from the blue emitter to the warmer, longer wavelengths of the red portion of the spectrum. In this way, warmer color temperatures not attainable with mere manipulation of gadolinium; i.e. yellow spectrum shift, are attainable.

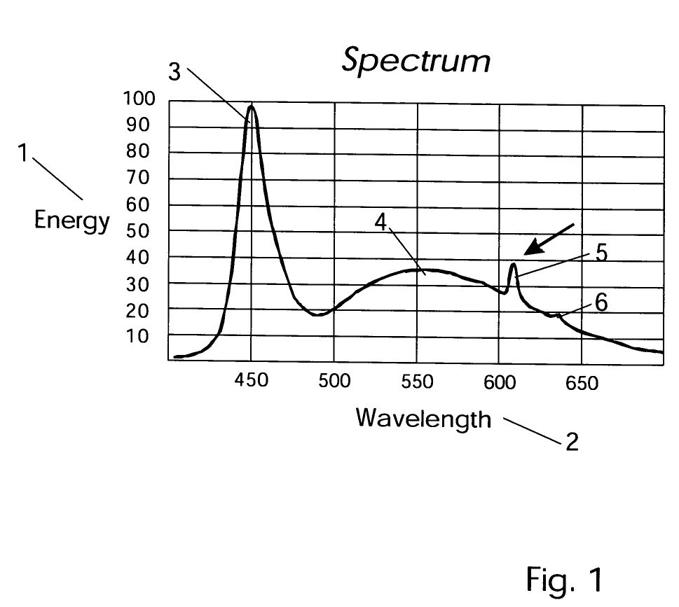

To more fully appreciate this, attention should be directed to the spectrum of FIG. 1. FIG. 1 shows a spectral output from a blue emitting semiconductor chip in conjunction with a YAG phosphor having dual activators where a first activator is cerium and a second activator is praseodymium. The emission energy 1 is plotted verse the wavelength 2. The spectrum has a first peak 3 in the blue region of the spectrum, at 450 nanometers due to the natural emission wavelength of the nitride semiconductor chip. This represents the light which passes through the wavelength shifting medium without interacting therewith. A second peak 4 appears at about 555 nanometers in the yellow/green region of the spectrum. This peak is due to phosphor activation by cerium. A third spectral peak 5 at approximately 610 nanometers is the result of a second activator: praseodymium. In addition, some secondary spectral activity 6 (minor peaks) is observed in the red portion of the spectrum.

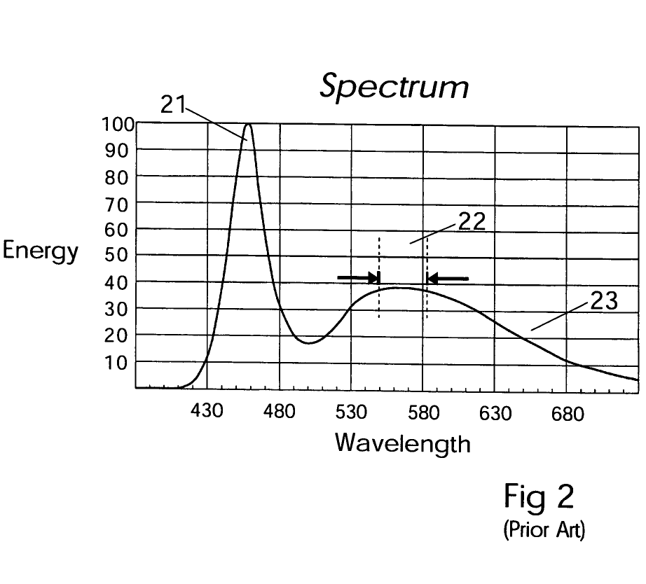

For comparison, FIG. 2 illustrates the prior art spectrum, a YAG phosphor activated only by cerium, pumped with a blue nitride diode. The spectrum includes a peak 21 of blue light due directly to the semiconductor emission. A second peak is movable about the range 22 as a result of adjustments to chemical ratios of the phosphor constituents. The plot clearly has little or no activity in the red region 23; i.e. at wavelengths greater than 620 nanometers.

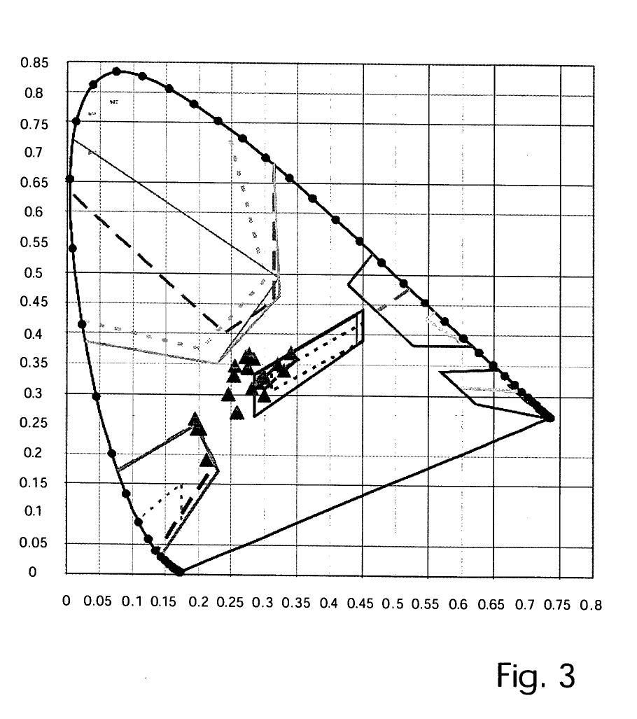

FIG. 3 is a chromacity diagram which illustrates the colors which can be represented by combinations of described blue emitting diodes and dual activated phosphors. The triangles indicate the various experimental devices made in accordance with these principles and actually measured in the laboratory.

It will be recognized that the precise nature of the emitter chip will affect the spectral output. While it is preferred that the center wavelength of the blue emitting chip is about 450 nanometers, these phosphors will be sufficiently stimulated by light in the wavelength range of about 410 to about 450 nm. When dual activator phosphors are combined with such semiconductor emitters, the emitter pumps the phosphor photonically and causes secondary emission having both yellow and red components to form a preferred white diode. In view of the current state of the art, diode semiconductors operable for emitting within this wavelength range are primarily characterized as nitride semiconductors of the type InGaAlN.

In most preferred versions, phosphors can be described as: Gd_{Z}Y_{3-X-Y-Z}Ce_{X}Pr_{Y}Ga₃Al₂O₁₂, where x=0.001-0.15; where y=0.0001-0.05; and where z=0.1-2.0. In order to get the intensities at preferable levels, it is useful to set the activators in proper ratio. When cerium is present in an amount between three and ten times that of praseodymium, the red peak contains the necessary amount of energy to produce a balanced white output. Such arrangements will result in a spectrum having a first spectral peak at about 575 nm=±50 nm, and a second spectral peak is at 630=±30 nm.

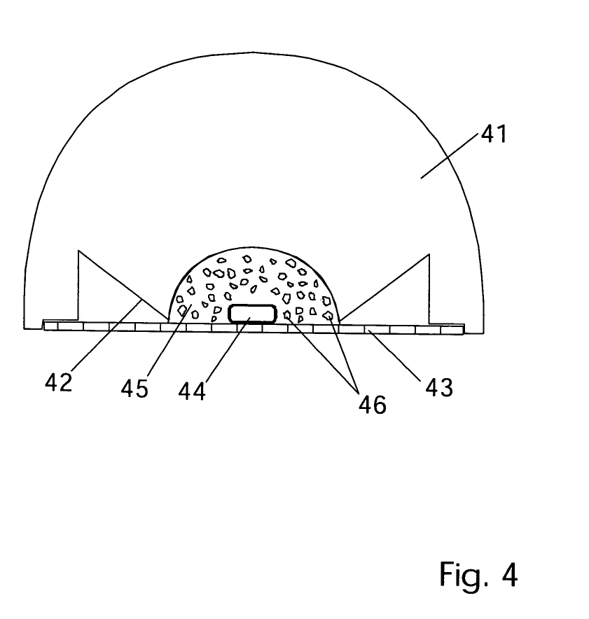

To get the best results from these new phosphors, they should be used in a suspension medium comprised of phosphor particles and soft gel. Gel aids with heat coupling and additionally provides for mechanical relief in expansion. This can be more readily understood with reference to FIG. 4 where an example system is shown. A plastic lens/cover element 41 having a reflecting mirror 42 is affixed to a base 43. A nitride semiconductor diode 44 lies beneath a medium comprised of a gel material 5 and phosphor particles 6 dispersed therein. While some phosphors are used in very fine powders where the average particle is about 2 microns on a side or less, these newly designed phosphors perform better when they are formed in a large particle state. In the phosphor formation processes, grinding is effected such that the crystals remain large. As large as 10 microns on a side average. In this way, preferred cross section and dispersion characteristics are observed. Further, it has been found through experimentation that a high ratio of gel to phosphor is preferred. When gel is mixed seventy percent by weight with respect to phosphor a preferred interaction cross section results and produces a more balanced white output. Other useful versions include those where 90% gel and 10% phosphor is used to form a wavelength shifting amalgam. In some versions where dispersion problems are not critical, phosphor particles may be ground to a more fine powder having an average size of about 2.5 microns on a side.

The index of refraction ratio between the gel and the phosphor also can be tuned in best versions. The index of refraction of the phosphor is adjusted by changing its components and particularly changing the concentration of yttrium to gadolinium to yield phosphor indices of about 1.9 to 2.0. Gel can be prepared with an index of refraction between about 1.4 and 1.7. As the ratio of nₚₕₒₛₚₕₒᵣ:n_{gel} decreases, the intensity follows with a decrease. In highest performance versions, this ratio is preferably between 1.1 and 1.4.

One will now fully appreciate how preferred broadband white emitting systems having improved color temperature tunability and dispersion characteristics are realized. Although the present inventions have been described in considerable detail with clear and concise language and with reference to certain preferred versions thereof including the best mode anticipated by the inventor, other versions are possible. Therefore, the spirit and scope of the invention should not be limited by the description of the preferred versions contained therein, but rather by the claims appended hereto

What is claimed is:

1) A yttrium-aluminum-garnet YAG phosphor composition of matter comprising dual activators.

2) A phosphor composition of claim 1, in combination with a semiconductor light emitting diode arranged to emit light in the spectral range from about 0.3 to about 0.48 microns.

3) A phosphor composition of claim 2, said semiconductor light emitting diode is a nitride based semiconductor.

4) A phosphor composition of claim 3, said dual activators are Ce and Pr.

5) A phosphor composition of claim 4, said phosphor is described by the formula: Gd_{Z}Y_{3-X-Y-Z}Ce_{X}Pr_{Y}Ga₃Al₂O₁₂,

6) A phosphor composition of claim 5, where x=0.001-0.15; where y=0.0001-0.05; and where z=0.1-2.0.

7) A phosphor composition of claim 6, said activators are provided in a ratio Ce:Pr is between about 3 and 10.

8) A phosphor of claim 4, said phosphor prepared as crystalline particles suspended colloid composition of silicon gel.

9) A phosphor composition of claim 8, the average size of said particles is greater than 10 microns on a side.

10) A phosphor composition of claim 9, entire composition comprises about 30% phosphor and 70% gel.

11) A phosphor composition of claim 8, said phosphor particles are at least 2.5 microns average diameter.

10) A phosphor composition of claim 8, said phosphor and said gel each having an associated index of refraction, the ratio of indices of refraction, nₚₕₒₛₚₕₒᵣ:n_{gel} is between about 1.1-1.4.

11) A phosphor composition of claim 1, having a first spectral peak at about 575 nm=±50 nm, and a second spectral peak is at 630=±30 nm.

12) A phosphor composition of claim 11, said first spectral peak is characterized as having a broad band, said second spectral peak is characterized as having a narrow band noticeably smaller than the first peak.

13) A phosphor composition of claim 2, light emitting diode arranged to emit light in the spectral range 455±10 nm.
